(19) United States
(12) Patent Application Publication
(10) Pub. No.: US 2022/0200304 A1
(43) Pub. Date: Jun. 23, 2022

(54) CABLE ASSEMBLY CAPABLE OF DETECTING BIDIRECTIONAL CHARGING-CURRENT

(71) Applicant: Cheng-Chun CHANG, Taipei City (TW)

(72) Inventor: Cheng-Chun CHANG, Taipei City (TW)

(21) Appl. No.: 17/362,642

(22) Filed: Jun. 29, 2021

(30) Foreign Application Priority Data
Dec. 21, 2020 (CN) 202011522080.9

(51) Int. Cl. H02J 7/00; H01R 13/66

(52) U.S. Cl. CPC H02J 7/0068; H02J 2207/30; H01R 13/665

(57) ABSTRACT

A cable assembly capable of detecting bidirectional charging-current, including a first interface, a second interface, and a cable electrically connected between the first interface and the second interface, the cable including a series resistor network, which has a first node, a common node, a second node, a first resistor and a second resistor, the first node being coupled to the first interface, the common node being coupled to a ground, the second node being coupled to the second interface, the first resistor being coupled between the first node and the common node, and the second resistor being coupled between the common node and the second node, whereby the first node and the second node can provide two single-end voltages or two differential voltages to represent a forward charging current and a reverse charging current respectively.

### BACKGROUND OF THE INVENTION

### Field of the Invention

The invention relates to a charging device, in particular to a cable assembly capable of detecting bidirectional charging-current.

### Description of the Related Art

Electronic devices such as mobile phones and tablet computers are already indispensable devices in the modern society. Charging cables are often used to charge them. Nowadays, there are many kinds of charging cables. Both ends of a charging cable can be either a standard USB interface or a Type-C interface. Since both ends of the charging cable can be connected to an electronic device, and the electronic devices at two ends can charge each other according to an agreement, the charging cable can therefore realize two-way charging. In addition, there are also charging cables used as relay cable or extension cable, which often also provide a two-way charging function. Moreover, as there are various interfaces for transmitting power and signals, it is not conducive to the manufacture and promotion of many products. Therefore, it can be expected that product associations and related organizations will unify the interface types to a common type. As Type-C interface possesses an overwhelming leading edge on the performance of signal transmission, therefore, the future common data interface is very likely the Type-C interface. In this way, the interfaces at both ends of the existing charging cable will be the Type-C interface.

In addition, when a cable is expected to provide a charging current detection function, a simple circuit such as a resistor is commonly seen embedded in a ground line of the cable. However, this arrangement can only be used to detect a unidirectional charging current. When the cable is connected with a reverse orientation between a power source apparatus and a power receiving apparatus, the cable will not be able to detect the charging current due to a negative voltage across the resistor, and therefore cannot display a charging current or a charging power, nor can it provide an over-current protection, and this can compromise the safety of normal operation, and will make users mistakenly believe that the charging cable has failed.

Therefore, there is an urgent need for a bidirectional charging cable structure that can solve the above-mentioned problems.

### SUMMARY OF THE INVENTION

The main objective of the invention is to provide a cable assembly capable of detecting a forward charging current and a reverse charging current flowing through a cable thereof

To attain the aforementioned objective, a cable assembly capable of detecting bidirectional charging-current is proposed, including a first interface, a second interface, and a cable electrically connected between the first interface and the second interface, characterized in that:

the cable including a series resistor network, which has a first node, a common node, a second node, a first resistor and a second resistor, the first node being coupled to the first interface, the common node being coupled to a ground, the second node being coupled to the second interface, the first resistor being coupled between the first node and the common node, and the second resistor being coupled between the common node and the second node; and

when in operation, a forward charging current is represented by a first single-end voltage at the first node or by a first differential voltage across the first node and the second node, and a reverse charging current is represented by a second single-end voltage at the second node or by a second differential voltage across the second node and the first node.

As opposed to the prior art, the present invention is equipped with a concise and symmetric bidirectional current sensing circuit on a charging current path for detecting not only the forward charging current but both the forward charging current and the reverse charging current. In addition, due to the concise bidirectional current sensing circuit, the cable assembly of the present invention can be implemented with low cost and can surely detect a charging current when connected between a power source electronic equipment, such as a personal computer, and a power receiver equipment, such as a handheld device, without the need of taking the trouble to discriminate which connector is for the power source equipment and which connector is for the power receiver equipment.

In one embodiment, the cable further includes a control unit coupled with the first node and the second node to receive the first single-end voltage and the second single-end voltage to sense the forward charging current and the reverse charging current respectively.

In one embodiment, the cable further includes a control unit and an amplifier circuit, the amplifier circuit being coupled with the first node and the second node to generate a first output voltage according to the first differential voltage and a second output voltage according to the second differential voltage, and the control unit being coupled with the amplifier circuit to receive the first output voltage and the second output voltage to sense the forward charging current and the reverse charging current respectively.

In one embodiment, the control unit includes a processing unit and a charging switch, the processing unit being used to control the charging switch according to a comparison result of a preset threshold with the first single-end voltage or the second single-end voltage.

In one embodiment, the control unit includes a processing unit and a charging switch, the processing unit being used to control the charging switch according to a comparison result of a preset threshold with the first output voltage or the second output voltage.

In one embodiment, the preset threshold corresponds to an equipment-fully-charged current, and the processing unit will switch off the charging switch when the first single-end voltage or the second single-end voltage is lower than the preset threshold.

In one embodiment, the preset threshold corresponds to an equipment-fully-charged current, and the processing unit will switch off the charging switch when the first output voltage or the second output voltage is lower than the preset threshold.

In one embodiment, the cable assembly further includes a display unit, and the control unit drives the display unit to display the forward charging current or the reverse charging current.

In one embodiment, the cable assembly further includes a voltage detection unit, where the voltage detection unit is used to detect a charging voltage, and the control unit derives a charging power value according to a product of the charging voltage and the forward charging current or a product of the charging voltage and the reverse charging current, and drives the display unit to display the charging power value.

In one embodiment, the voltage detection unit includes a voltage dividing circuit coupled between a supply voltage line of the cable and the ground, the voltage dividing circuit includes a third resistor and a fourth resistor connected in series, and a common node between the third resistor and the fourth resistor is used to provide the charging voltage.

In one embodiment, the control unit and the display unit are installed at the first interface or the second interface, or on the cable.

In one embodiment, both the first interface and the second interface are USB connectors, and can be of a same type or different types.

In one embodiment, both the first interface and the second interface are Type-C USB connectors.

In one embodiment, the cable is also provided with signal lines connected between the first interface and the second interface.

For possible embodiments, the first interface and the second interface each can be a magnetic engagement interface, a plug-in interface or a wireless charging interface.

### BRIEF DESCRIPTION OF THE DRAWINGS

FIG. 1 illustrates a circuit diagram of the cable assembly according to a first embodiment of the present invention.

FIG. 2 illustrates a schematic diagram of the cable assembly according to an embodiment of the present invention.

FIG. 3 illustrates a schematic diagram of the cable assembly according to another embodiment of the present invention.

FIG. 4 illustrates a circuit diagram of the cable assembly according to a second embodiment of the present invention.

### DETAILED DESCRIPTION OF THE PREFERRED EMBODIMENTS

To make it easier for our examiner to understand the objective of the invention, its structure, innovative features, and performance, we use preferred embodiments together with the accompanying drawings for the detailed description of the invention.

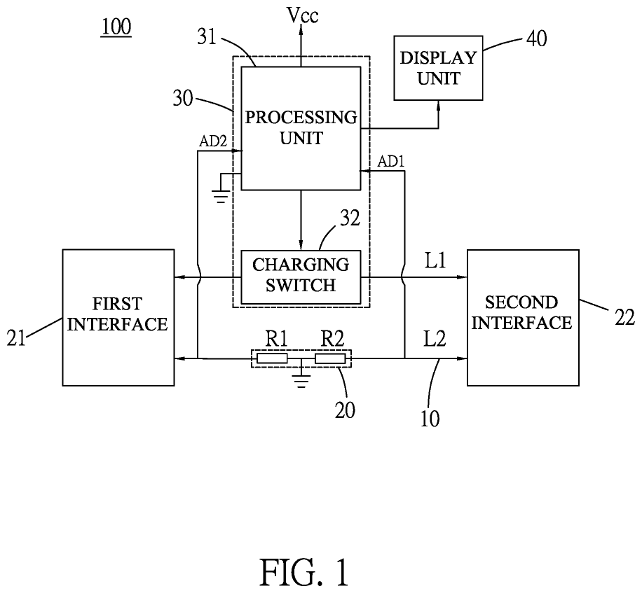

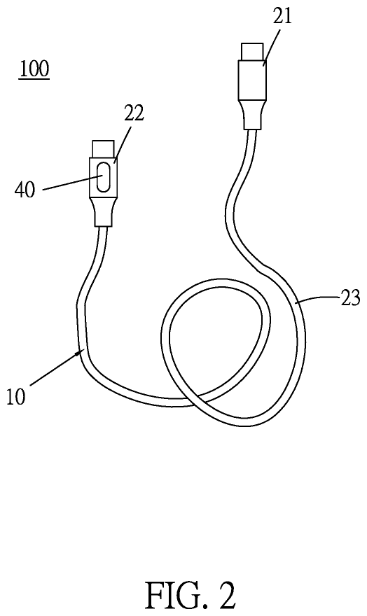

Please refer to FIGS. 1 and 2, which illustrate a first embodiment of the invention. As illustrated in the figures, a cable assembly 100 includes a charging current path 10 embedded with a current detection network 20. The charging current path 10 includes a first interface 21, a second interface 22 and a cable 23 for transmitting a forward charging current from the first interface 21 to the second interface 22 and transmitting a reverse charging current from the second interface 22 to the first interface 21. The cable 23 is provided with a supply voltage line L1 and a ground line L2, the supply voltage line L1 is connected between a power terminal of the first interface 21 and a power terminal of the second interface 22, and the ground line L2 is connected between a ground terminal of the first interface 21 and a ground terminal of the second interface 22.

In addition, the current detection network 20 is embedded in the ground line L2 and includes a series resistor network, which has a first node, a common node, a second node, a first resistor R1 and a second resistor R2, the first node being coupled to the first interface 21, the common node being coupled to a ground, the second node being coupled to the second interface 22, the first resistor R1 being coupled between the first node and the common node, and the second resistor R2 being coupled between the common node and the second node.

In addition, the first resistor R1 and the second resistor R2 can be of a same resistance value or different resistance values for sensing the forward charging current and the reverse charging current respectively.

In addition, the cable assembly 100 can serve as a charging extension cable, or can be connected with an adapter connector to serve as a charging cable for a charging device, or can be directly connected between two electronic apparatuses to transmit a forward charging current or a reverse charging current. The electronic apparatus to be charged can be a handheld device, or a power bank. The power supply device can be a power bank, a power adapter, or an electronic apparatus such as a handheld device. The invention is mainly used for low-voltage charging applications.

In addition, the cable assembly 100 further includes a control unit 30 connected to the first node and the second node to obtain the information of the forward charging current and the reverse charging current flowing through the charging current path 10.

In addition, the control unit 30 can compare a first single-end voltage at the first node with a second single-end voltage at the second node to determine whether a charging current is a forward charging current or a reverse charging current; or determine a charging current as a forward charging current when a first single-end voltage at the first node is a positive voltage, or as a reverse charging current when a second single-end voltage at the second node is a positive voltage.

To be specific, the control unit 30 has an analog input end AD1 for receiving the second single-end voltage, and an analog input end AD2 for receiving the first single-end voltage. When a forward charging operation takes place, a forward charging current will flow through the first resistor R1 and the second resistor R2 in a direction from the first interface 21 to the second interface 22, causing the first single-end voltage to be positive and the second single-end voltage to be negative, and the control unit 30 will derive the value of the forward charging current by dividing the first single-end voltage with the resistance value of the first resistor R1; and when a reverse charging operation takes place, a reverse charging current will flow through the second resistor R2 and the first resistor R1 in a direction from the second interface 22 to the first interface 21, causing the second single-end voltage to be positive and the first single-end voltage to be negative, and the control unit 30 will derive the value of the reverse charging current by dividing the second single-end voltage with the resistance value of the second resistor R2.

In addition, the control unit 30 includes a processing unit 31 and a charging switch 32, where the processing unit 31 uses the first single-end voltage and the second single-end voltage to determine the value of the forward charging current and the value of the reverse charging current, and switches off the charging switch when the first single-end voltage or the second single-end voltage is below a threshold voltage corresponding to a preset threshold current, which indicates a fully-charged status of a charging process, so as to prevent over charging of an electronic apparatus.

In addition, the threshold voltage corresponds to an equipment-fully-charged current, and the processing unit 31 will switch off the charging switch 32 when the first single-end voltage or the second single-end voltage is lower than the threshold voltage.

In addition, the cable assembly 100 further includes a display unit 40, and the control unit 30 controls the display unit 40 to display the charging current flowing through the charging current path.

In addition, the first interface 21 and the second interface 22 can be USB connectors. Specifically, either of the first interface 21 and the second interface 22 can be a standard USB connector, a lightning USB connector, a mini USB connector, a micro USB connector or a Type-C USB connector.

To be specific, the first interface 21 and the second interface 22 can be of a same type. Referring to FIG. 2, the first interface 21 is a Type-C USB connector, and the second interface 22 is a Type-C USB connector. With both terminals of the cable assembly 100 being equipped with a Type-C USB connector to transmit a forward charging current or a reverse charging current, or exchange data, the cable assembly 100 can be used in a variety of current and future applications.

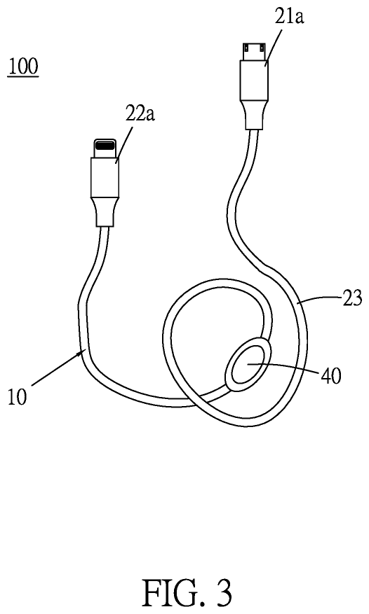

Similarly, the first interface 21 and the second interface 22 can both be Micro USB connectors. On the other hand, the first interface 21 and the second interface 22 can be of different types. As illustrated in FIG. 3, the first interface 21a is a micro USB connector, and the second interface 22a is a lightning USB connector.

In addition, the cable 23 is also provided with signal lines electrically connected between the signal ends of the first interface 21 and the second interface 22, so that cable assembly 100 can be used for data transmission.

In this embodiment, the first interface 21 and the second interface 22 are plug-in interfaces. For alternative embodiments, the first interface 21 and the second interface 22 can also be a magnetic engagement interface, a wireless charging interface, or other connecting interfaces.

In addition, although the control unit 30 and the display unit 40 are installed on the cable 23 (as shown in FIG. 3), they can also be installed on the first interface 21 or the second interface 22.

For possible embodiments, the display unit 40 can be a display screen, a digital display, an LED panel, and so on.

In addition, apart from driving the display unit 40 to display the sensed charging current, the control unit 30 can use the sensed charging current for over-current protection, charging energy calculation, fault determination, and so on.

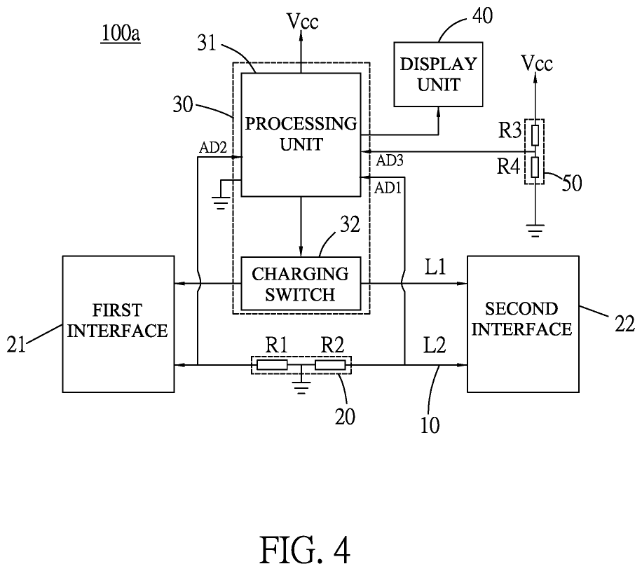

Please refer to FIG. 4, which illustrates a second embodiment of the invention. In this embodiment, the cable assembly 100a further includes a voltage detection unit 50, which detects a charging voltage for the charging current path 10, the control unit 30 derives a charging power value according to a product of the charging current and the charging voltage, and drives the display unit 40 to display the charging power value. In addition, the control unit 30 can also drive the display unit 40 to display the charging voltage and/or the charging current. That is, the control unit 30 can optionally select at least one of the charging current, the charging voltage, and the charging power for display, and the selection can be a fixed selection or a configurable selection. For example, the control unit 30 can have a dip switch for users to configure the selection.

Specifically, the voltage detection unit 50 includes a voltage dividing circuit coupled between a supply voltage line L1 and the ground, the voltage dividing circuit includes a third resistor R3 and a fourth resistor R4 connected in series, and a common node between the third resistor R3 and the fourth resistor R4 is used to provide a sensed voltage for the charging voltage. It is to be noted that the embodiment of the voltage detection unit 50 is not limited to the disclosure of FIG. 4, other circuits capable of voltage sensing can also be used to implement the voltage detection unit 50.

It is to be noted that although the disclosure above uses a single-end voltage scheme for charging current representation, however, a differential voltage scheme can also be adopted for representing the charging current. That is, the present invention can be generalized as:

A cable assembly capable of detecting bidirectional charging-current, including a first interface, a second interface, and a cable electrically connected between the first interface and the second interface, characterized in that: the cable including a series resistor network, which has a first node, a common node, a second node, a first resistor and a second resistor, the first node being coupled to the first interface, the common node being coupled to a ground, the second node being coupled to the second interface, the first resistor being coupled between the first node and the common node, and the second resistor being coupled between the common node and the second node; and when in operation, a forward charging current is represented by a first single-end voltage at the first node or by a first differential voltage across the first node and the second node, and a reverse charging current is represented by a second single-end voltage at the second node or by a second differential voltage across the second node and the first node.

In summary, thanks to the concise and symmetric structure of the bidirectional current detection network 20, the cable assembly of the present invention can be implemented with low cost and can surely detect a charging current when connected between a power source electronic equipment and a power receiver equipment without the need of taking the trouble to discriminate which connector is for the power source equipment and which connector is for the power receiver equipment. Therefore, the cable assembly of the present invention is user-friendly and can provide functions of charging current detection, charging power detection and over current detection with high reliability.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A cable assembly capable of detecting bidirectional charging-current, including a first interface, a second interface, and a cable electrically connected between the first interface and the second interface, characterized in that:
the cable including a series resistor network, which has a first node, a common node, a second node, a first resistor and a second resistor, the first node being coupled to the first interface, the common node being coupled to a ground, the second node being coupled to the second interface, the first resistor being coupled between the first node and the common node, and the second resistor being coupled between the common node and the second node; and
when in operation, a forward charging current is represented by a first single-end voltage at the first node or by a first differential voltage across the first node and the second node, and a reverse charging current is represented by a second single-end voltage at the second node or by a second differential voltage across the second node and the first node.

2. The cable assembly according to claim 1, wherein the cable further includes a control unit coupled with the first node and the second node to receive the first single-end voltage and the second single-end voltage to sense the forward charging current and the reverse charging current respectively.

3. The cable assembly according to claim 1, wherein the cable further includes a control unit and an amplifier circuit, the amplifier circuit being coupled with the first node and the second node to generate a first output voltage according to the first differential voltage and a second output voltage according to the second differential voltage, and the control unit being coupled with the amplifier circuit to receive the first output voltage and the second output voltage to sense the forward charging current and the reverse charging current respectively.

4. The cable assembly according to claim 2, wherein the control unit includes a processing unit and a charging switch, the processing unit being used to control the charging switch according to a comparison result of a preset threshold with the first single-end voltage or the second single-end voltage.

5. The cable assembly according to claim 3, wherein the control unit includes a processing unit and a charging switch, the processing unit being used to control the charging switch according to a comparison result of a preset threshold with the first output voltage or the second output voltage.

6. The cable assembly according to claim 4, wherein the preset threshold corresponds to an equipment-fully-charged current, and the processing unit will switch off the charging switch when the first single-end voltage or the second single-end voltage is lower than the preset threshold.

7. The cable assembly according to claim 5, wherein the preset threshold corresponds to an equipment-fully-charged current, and the processing unit will switch off the charging switch when the first output voltage or the second output voltage is lower than the preset threshold.

8. The cable assembly according to claim 2, further comprising a display unit, wherein the control unit drives the display unit to display the forward charging current or the reverse charging current.

9. The cable assembly according to claim 3, further comprising a display unit, wherein the control unit drives the display unit to display the forward charging current or the reverse charging current.

10. The cable assembly according to claim 2, further comprising a voltage detection unit and a display unit, wherein the voltage detection unit is used to detect a charging voltage, and the control unit derives a charging power value according to a product of the charging voltage and the forward charging current or a product of the charging voltage and the reverse charging current, and drives the display unit to display the charging power value.

11. The cable assembly according to claim 3, further comprising a voltage detection unit and a display unit, wherein the voltage detection unit is used to detect a charging voltage, and the control unit derives a charging power value according to a product of the charging voltage and the forward charging current or a product of the charging voltage and the reverse charging current, and drives the display unit to display the charging power value.

12. The cable assembly according to claim 10, wherein the voltage detection unit includes a voltage dividing circuit coupled between a supply voltage line of the cable and the ground, the voltage dividing circuit includes a third resistor and a fourth resistor connected in series, and a common node between the third resistor and the fourth resistor is used to provide the charging voltage.

13. The cable assembly according to claim 11, wherein the voltage detection unit includes a voltage dividing circuit coupled between a supply voltage line of the cable and the ground, the voltage dividing circuit includes a third resistor and a fourth resistor connected in series, and a common node between the third resistor and the fourth resistor is used to provide the charging voltage.

14. The cable assembly according to claim 8, wherein the control unit and the display unit are installed at the first interface or the second interface, or on the cable.

15. The cable assembly according to claim 9, wherein the control unit and the display unit are installed at the first interface or the second interface, or on the cable.

16. The cable assembly according to claim 10, wherein the control unit and the display unit are installed at the first interface or the second interface, or on the cable.

17. The cable assembly according to claim 11, wherein the control unit and the display unit are installed at the first interface or the second interface, or on the cable.

18. The cable assembly according to claim 1, wherein both the first interface and the second interface are USB connectors.

19. The cable assembly according to claim 18, wherein both the USB connectors are type C USB connectors.

20. The cable assembly according to claim 1, wherein the first interface and the second interface are both selected from a group consisting of a magnetic engagement interface, a plug-in interface and a wireless charging interface.
